(19) United States
(12) Patent Application Publication
(10) Pub. No.: US 2023/0119602 A1
(43) Pub. Date: Apr. 20, 2023

(54) RESONANCE DEVICE, COLLECTIVE SUBSTRATE, AND RESONANCE DEVICE MANUFACTURING METHOD

(71) Applicant: Murata Manufacturing Co., Ltd., Nagaokakyo-shi (JP)

(72) Inventors: Masakazu FUKUMITSU, Nagaokakyo-shi (JP); Takashi UEDA, Nagaokakyo-shi (JP)

(21) Appl. No.: 18/067,256

(22) Filed: Dec. 16, 2022

Related U.S. Application Data
(63) Continuation of application No. PCT/JP2021/010275, filed on Mar. 15, 2021.

(30) Foreign Application Priority Data
Aug. 24, 2020 (JP) 2020-140876

(51) Int. Cl. H03H 9/05; H03H 9/24; H03H 3/007; H03H 9/10; H03H 9/02

(52) U.S. Cl. CPC H03H 9/0595; H03H 9/2489; H03H 3/0072; H03H 9/1057; H03H 9/02433; H03H 2009/02488

(57) ABSTRACT

A resonance device that includes a MEMS substrate including a resonator having a vibrating portion, a holding portion configured to hold the vibrating portion, and an isolation groove that surrounds the vibrating portion in a plan view of the resonance device; and an upper lid facing the MEMS substrate with the resonator interposed therebetween and that includes a connection wiring electrically connected to the vibrating portion.

### CROSS REFERENCE TO RELATED APPLICATIONS

The present application is a continuation of International application No. PCT/JP2021/010275, filed Mar. 15, 2021, which claims priority to Japanese Patent Application No. 2020-140876, filed Aug. 24, 2020, the entire contents of each of which are incorporated herein by reference.

### FIELD OF THE INVENTION

The present invention relates to a resonance device, a collective substrate, and a resonance device manufacturing method.

### BACKGROUND OF THE INVENTION

Conventionally, a device manufactured with use of micro electro mechanical systems (MEMS) technology, for instance, has prevailed. As for this device, a plurality of devices are formed on a collective substrate (wafer), for instance, and individuating (chipping) into the devices is thereafter carried out with split of the wafer.

A resonance device including a resonator in which a holding portion, support arms, and vibrating portions are electrically connected with a degenerate silicon (Si) substrate or metal film interposed therebetween is disclosed in Patent Document 1, for instance. According to Patent Document 1, a frequency regulation step of regulating a resonant frequency of the vibrating portions is carried out with use of an ion trimming method or the like in a state of the collective substrate preceding the split into the resonance devices.

Patent Document 1: International Publication No. 2016/174789

### SUMMARY OF THE INVENTION

In the collective substrate disclosed in Patent Document 1, however, the plurality of resonance devices are placed so as to adjoin one another and there is continuity between the holding portions of adjoining resonators. Therefore, noises generated in trimming processing or the like are prone to be propagated to the vibrating portions of the adjoining resonance devices via the holding portions. As a result, when the resonant frequency of the vibrating portions is regulated, for instance, there has been a fear that regulation accuracy for the resonant frequency may be lowered with lowering in measurement accuracy due to propagation noises.

The present invention has been produced in consideration of such circumstances and it is one of objects thereof to provide a resonance device, a collective substrate, and a resonance device manufacturing method by which propagation of the noises via the holding portions can be reduced.

A resonance device according to an aspect of the present invention includes: a first substrate including a resonator having a vibrating portion, a holding portion configured to hold the vibrating portion, and an isolation groove that surrounds the vibrating portion in a plan view of the resonance device; and a second substrate facing the first substrate with the resonator interposed therebetween and that includes a first connection portion electrically connected to the vibrating portion.

A collective substrate according to another aspect of the present invention for manufacture of a resonance device includes: a first substrate having a plurality of resonators each having a vibrating portion, a holding portion configured to hold the vibrating portion, and an isolation groove that surrounds the vibrating portion in a plan view of the collective substrate; and a second substrate facing the first substrate with the plurality of resonators interposed therebetween and that includes a plurality of first connection portions respectively electrically connected to the vibrating portions of the plurality of resonators.

A method of manufacturing resonance devices according to still another aspect of the present invention includes: preparing a first substrate including a plurality of resonators each having a vibrating portion, a holding portion configured to hold the vibrating portion, and an isolation groove that surrounds the vibrating portion in a plan view of the first substrate; placing a second substrate so as to face the first substrate with the plurality of resonators interposed therebetween and that includes a plurality of first connection portions to be respectively and electrically connected to the vibrating portions of the plurality of resonators; jointing the first substrate to the second substrate; and splitting the first substrate and the second substrate along split lines so as to form a plurality of resonance devices.

According to the present invention, propagation of noises via the holding portions can be reduced.

### BRIEF DESCRIPTION OF THE DRAWINGS

FIG. 1 is a perspective view schematically illustrating an exterior of a resonance device in an embodiment.

FIG. 2 is an exploded perspective view schematically illustrating a structure of the resonance device illustrated in FIG. 1.

FIG. 3 is a plan view schematically illustrating a structure of a resonator illustrated in FIG. 2.

FIG. 4 is a sectional view, taken along the X axis, schematically illustrating a stacking structure of the resonance device illustrated in FIG. 1.

FIG. 5 is a sectional view, taken along the Y axis, schematically illustrating the stacking structure of the resonance device illustrated in FIG. 1.

FIG. 6 is a plan view schematically illustrating the resonator illustrated in FIGS. 1 to 5 and wiring therearound.

FIG. 7 is an enlarged sectional view schematically illustrating a stacking structure of coupling members illustrated in FIG. 6.

FIG. 8 is an exploded perspective view schematically illustrating an exterior of a collective substrate in the embodiment.

FIG. 9 is an enlarged fragmentary view in which an area A illustrated in FIG. 8 is enlarged.

FIG. 10 is a flowchart representing a manufacturing method of the resonance device in the embodiment.

FIG. 11 is a plan view schematically illustrating a resonator of a resonance device in a modification of the embodiment and wiring therearound.

FIG. 12 is an enlarged sectional view schematically illustrating a stacking structure of coupling members illustrated in FIG. 11.

### DETAILED DESCRIPTION OF THE PREFERRED EMBODIMENTS

Hereinbelow, an embodiment of the present invention will be described. In a following description of the drawings, the same or similar components will be represented with use of the same or similar reference characters. The drawings are exemplary, sizes or shapes of portions are schematic, and technical scope of the present invention should not be understood with limitation to the embodiment.

### Resonance Device

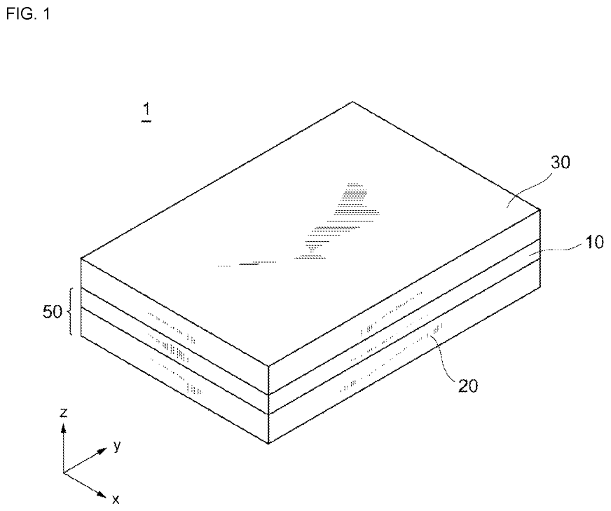

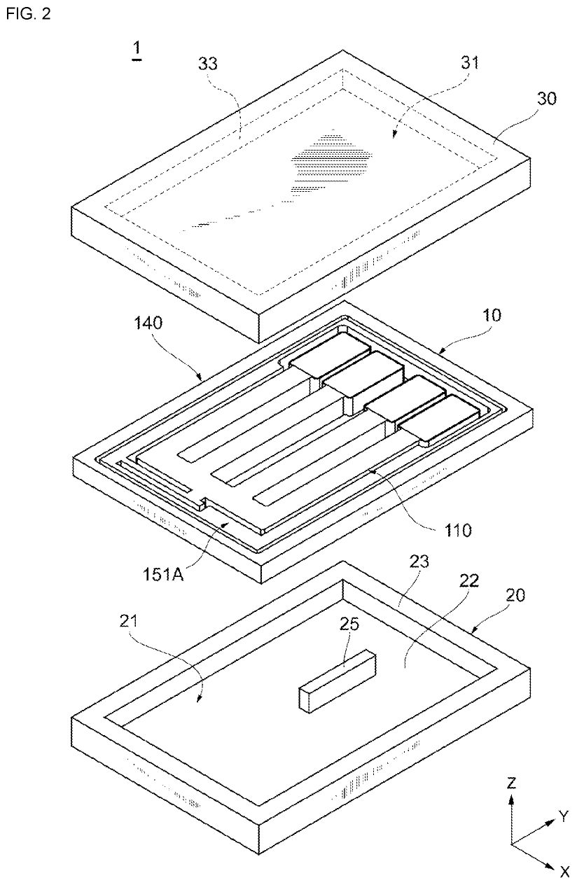

Initially, a schematic configuration of a resonance device according to the embodiment will be described with reference to FIGS. 1 and 2. FIG. 1 is a perspective view schematically illustrating an exterior of a resonance device 1 in the embodiment. FIG. 2 is an exploded perspective view schematically illustrating a structure of the resonance device 1 illustrated in FIG. 1.

As illustrated in FIGS. 1 and 2, the resonance device 1 includes a resonator 10, and a lower lid 20 and an upper lid 30 that form a vibration space in which the resonator 10 vibrates. That is, the resonance device 1 is configured by the lower lid 20, the resonator 10, a joint portion 60 to be described later, and the upper lid 30 that are stacked in order of mention. Incidentally, a MEMS substrate 50 (the lower lid 20 and the resonator 10) of the embodiment corresponds to an example of “first substrate” of the invention and the upper lid 30 of the embodiment corresponds to an example of “second substrate” of the invention.

Hereinbelow, configurations of the resonance device 1 will be described. Incidentally, the description below will be given with reference to a side of the resonance device 1 provided with the upper lid 30 as upper (or front) side and reference to a side of the resonance device 1 provided with the lower lid 20 as lower (or back) side.

The resonator 10 is a MEMS vibrator produced with use of MEMS technology. The resonator 10 and the upper lid 30 are jointed with the joint portion 60 interposed therebetween. Further, the resonator 10 and the lower lid 20 are each formed with use of a silicon (Si) substrate (which will be referred to as “Si substrate” hereinbelow) and the Si substrates are jointed to each other. Incidentally, the resonator 10, the lower lid 20, and the upper lid 30 may be each formed with use of a silicon on insulator (SOI) substrate in which silicon layers and silicon oxide film are stacked.

The upper lid 30 extends in a shape of a flat plate along the XY plane and a recessed portion 31 shaped like a flat rectangular parallelepiped, for instance, is formed on a back surface thereof. The recessed portion 31 is surrounded by side walls 33 and forms a portion of the vibration space that is a space in which the resonator 10 vibrates. Incidentally, the upper lid 30 may lack the recessed portion 31 and may be shaped like a flat plate. Further, a getter layer to absorb outgas may be formed on a surface of the recessed portion 31 of the upper lid 30 on a side of the resonator 10.

The lower lid 20 includes a bottom plate 22 provided along the XY plane and shaped like a rectangular flat plate, and side walls 23 extending in the Z axis direction, that is, a stacking direction for the lower lid 20 and the resonator 10 from a peripheral portion of the bottom plate 22. A recessed portion 21 defined by a front surface of the bottom plate 22 and inside surfaces of the side walls 23 is formed on a surface of the lower lid 20 that faces the resonator 10. The recessed portion 21 forms a portion of the vibration space for the resonator 10. Incidentally, the lower lid 20 may lack the recessed portion 21 and may be shaped like a flat plate. Further, a getter layer to absorb outgas may be formed on a surface of the recessed portion 21 of the lower lid 20 on a side of the resonator 10.

Further, the lower lid 20 includes a protruding portion 25 formed on the front surface of the bottom plate 22. A detailed configuration of the protruding portion 25 will be described later.

By jointing of the upper lid 30 and the resonator 10 and the lower lid 20, the vibration space for the resonator 10 is airtightly sealed so that a vacuum state is maintained. This vibration space may be filled with gas such as inert gas, for instance.

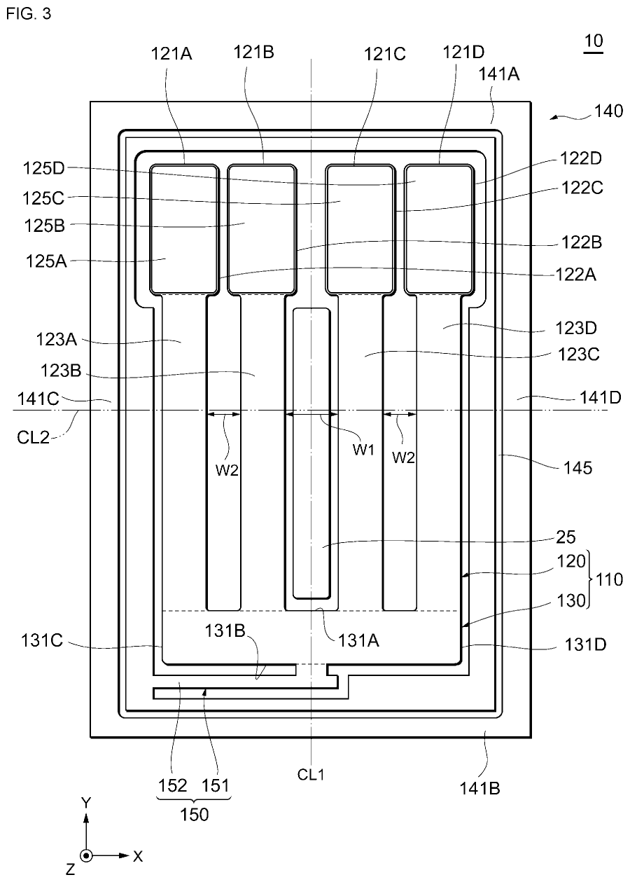

Subsequently, a schematic configuration of the resonator in the resonance device according to the embodiment will be described with reference to FIG. 3. FIG. 3 is a plan view schematically illustrating a structure of the resonator 10 illustrated in FIG. 2.

As illustrated in FIG. 3, the resonator 10 is the MEMS vibrator produced with use of the MEMS technology and vibrates with an out-of-plane bending vibration mode as principal vibration (which may be referred to as “main mode” hereinbelow) in the XY plane in an orthogonal coordinate system of FIG. 3. Incidentally, the resonator 10 is not limited to a resonator in which the out-of-plane bending vibration mode is used. The resonator of the resonance device 1 may be a resonator in which a spreading vibration mode, a thickness longitudinal vibration mode, a Lamb wave vibration mode, an in-plane bending vibration mode, or a surface acoustic wave vibration mode is used, for instance. These vibrators are applied to timing devices, RF filters, duplexers, ultrasonic transducers, gyro sensors, acceleration sensors, and the like, for instance. Further, the vibrators may be used for piezoelectric mirrors having an actuator function, piezoelectric gyros, piezoelectric microphones having a pressure sensor function, ultrasonic vibration sensors, or the like. Moreover, the vibrators may be applied to electrostatic MEMS elements, electromagnetic MEMS elements, or piezoresistive MEMS elements.

The resonator 10 includes a vibrating portion 110, a holding portion 140, and a support arm portion 150.

The vibrating portion 110 has rectangular contours extending along the XY plane in the orthogonal coordinate system of FIG. 3. The vibrating portion 110 is placed in an inner side portion of the holding portion 140 and a space is formed between the vibrating portion 110 and the holding portion 140 with specified intervals. In an example of FIG. 3, the vibrating portion 110 includes an excitation portion 120 made of four vibrating arms 121A to 121D (which may be collectively referred to as “vibrating arms 121” hereinbelow) and a base portion 130. Incidentally, the number of the vibrating arms is not limited to four and may be set at any desired number greater than or equal to one, for instance. In the embodiment, the excitation portion 120 and the base portion 130 are integrally formed.

The vibrating arms 121A, 121B, 121C, and 121D each extend along the Y axis direction and are provided in parallel at specified intervals in the X axis direction in order of mention. One end of the vibrating arm 121A is a fixed end connected to a fore end portion 131A of the base portion 130 that will be described later and the other end of the vibrating arm 121A is an open end provided far from the fore end portion 131A of the base portion 130. The vibrating arm 121A includes a mass addition portion 122A formed on a side of the open end and an arm portion 123A extending from the fixed end and connected to the mass addition portion 122A. Similarly, the vibrating arms 121B, 121C, and 121D respectively include mass addition portions 122B, 122C, and 122D and arm portions 123B, 123C, and 123D. Incidentally, the arm portions 123A to 123D each have a width on the order of 30 μm along the X axis direction and a length on the order of 400 μm along the Y axis direction, for instance.

In the excitation portion 120 of the embodiment, the two vibrating arms 121A and 121D are placed in outer side portions and the two vibrating arms 121B and 121C are placed in an inner side portion with respect to the X axis direction. A width (which will be referred to as “release width” hereinbelow) W1 of a gap formed between the arm portions 123B and 123C of the two vibrating arms 121B and 121C in the inner side portion is set greater than a release width W2 between the arm portions 123A and 123B of the vibrating arms 121A and 121B adjoining in the X axis direction and greater than the release width W2 between the arm portions 123D and 123C of the vibrating arms 121D and 121C adjoining in the X axis direction, for instance. The release width W1 is on the order of 25 μm, for instance, and the release width W2 is on the order of 10 μm, for instance. Thus, vibration characteristics and durability of the vibrating portion 110 are improved by setting of the release width W1 greater than the release width W2. Incidentally, in order that the resonance device 1 may be miniaturized, the release width W1 may be set smaller than the release width W2 or the release width W1 and the release width W2 may be set so as to make equal intervals.

The mass addition portions 122A to 122D include mass addition films 125A to 125D on respective front surfaces. Therefore, weights per unit length (which may be simply referred to as “weights” hereinbelow) of the mass addition portions 122A to 122D are respectively heavier than weights of the arm portions 123A to 123D. Thus, the vibration characteristics can be improved while the vibrating portion 110 is miniaturized. Further, the mass addition films 125A to 125D do not only have a function of increasing weights of extremity portions of the vibrating arms 121A to 121D but also has a function, as so-called frequency regulation film, of regulating resonant frequencies of the vibrating arms 121A to 121D with scraping of portions thereof, respectively.

In the embodiment, widths of the mass addition portions 122A to 122D along the X axis direction are on the order of 49 μm, for instance, and are greater than widths of the arm portions 123A to 123D along the X axis direction, respectively. Thus, the weights of the mass addition portions 122A to 122D can be further increased. For miniaturization of the resonator 10, the widths of the mass addition portions 122A to 122D along the X axis direction are preferably 1.5 or more times the widths of the arm portions 123A to 123D along the X axis direction, respectively. It is sufficient, however, if the weights of the mass addition portions 122A to 122D are respectively heavier than the weights of the arm portions 123A to 123D and the widths of the mass addition portions 122A to 122D along the X axis direction are not limited to the example of the embodiment. The widths of the mass addition portions 122A to 122D along the X axis direction may be smaller than or equal to the widths of the arm portions 123A to 123D along the X axis direction, respectively.

In plan view of the resonator 10 from above (which will be simply referred to as “plan view” hereinbelow), the mass addition portions 122A to 122D each have a curved shape substantially shaped like a rectangle and rounded at four corners, such as so-called R shape. Similarly, the arm portions 123A to 123D are each substantially shaped like a rectangle and have the R shapes in vicinities of the fixed ends connected to the base portion 130 and in vicinities of connection portions connected to the mass addition portions 122A to 122D, respectively. The shapes of the mass addition portions 122A to 122D and the arm portions 123A to 123D, however, are not limited to the example of the embodiment. For instance, the shapes of the mass addition portions 122A to 122D may be substantially like trapezoids or letters L. Further, the shapes of the arm portions 123A to 123D may be substantially like trapezoids. A bottomed groove portion having an opening on either of a front surface side and a back surface side or a hole portion having openings on both of the front surface side and the back surface side may be formed on each of the mass addition portions 122A to 122D and the arm portions 123A to 123D. The groove portion and the hole portion may be separated from side surfaces linking the front surface and the back surface or may have an opening on a side of the side surface.

In plan view, the base portion 130 includes the fore end portion 131A, a rear end portion 131B, a left end portion 131C, and a right end portion 131D. As described above, the fixed ends of the vibrating arms 121A to 121D are connected to the fore end portion 131A. A support arm 151 of the support arm portion 150 that will be described later is connected to the rear end portion 131B.

Each of the fore end portion 131A, the rear end portion 131B, the left end portion 131C, and the right end portion 131D is a portion of an outer peripheral portion of the base portion 130. Specifically, the fore end portion 131A and the rear end portion 131B are end portions extending in the X axis direction and are placed so as to be opposed to each other. The left end portion 131C and the right end portion 131D are end portions extending in the Y axis direction and are placed so as to be opposed to each other. Both ends of the left end portion 131C are respectively linked to one end of the fore end portion 131A and to one end of the rear end portion 131B. Both ends of the right end portion 131D are respectively linked to the other end of the fore end portion 131A and to the other end of the rear end portion 131B.

In plan view, the base portion 130 has a substantially rectangular shape having the fore end portion 131A and the rear end portion 131B as long sides and having the left end portion 131C and the right end portion 131D as short sides. The base portion 130 is formed substantially in plane symmetry with respect to an imaginary plane defined along a center line CL1 with respect to the X axis direction that is a perpendicular bisector for the fore end portion 131A and the rear end portion 131B. That is, it can be said that the base portion 130 is formed substantially in line symmetry with respect to the center line CL1. Incidentally, the shape of the base portion 130 is not limited to a case of the rectangular shape illustrated in FIG. 3 and may be another shape configured substantially in line symmetry with respect to the center line CL1. For instance, the shape of the base portion 130 may be like a trapezoid in which one of the fore end portion 131A and the rear end portion 131B is longer than the other. Further, at least one of the fore end portion 131A, the rear end portion 131B, the left end portion 131C, and the right end portion 131D may be bent or curved.

Incidentally, the imaginary plane corresponds to a symmetry plane for the vibrating portion 110 as a whole and the center line CL1 corresponds to a center line of the vibrating portion 110 as a whole with respect to the X axis direction. Therefore, the center line CL1 is a line extending through a center of the vibrating arms 121A to 121D with respect to the X axis direction and is located between the vibrating arm 121B and the vibrating arm 121C. Specifically, the adjoining vibrating arms 121A and 121B are respectively formed in symmetry to the adjoining vibrating arms 121D and 121C with respect to the center line CL1.

In the base portion 130, a base portion length that is the longest distance in the Y axis direction between the fore end portion 131A and the rear end portion 131B is on the order of 20 μm, for instance. Meanwhile, a base portion width that is the longest distance in the X axis direction between the left end portion 131C and the right end portion 131D is on the order of 180 μm, for instance. Incidentally, in the example illustrated in FIG. 3, the base portion length corresponds to a length of the left end portion 131C or the right end portion 131D and the base portion width corresponds to a length of the fore end portion 131A or the rear end portion 131B.

The holding portion 140 is configured so as to hold the vibrating portion 110. More particularly, the holding portion 140 is configured so that the vibrating arms 121A to 121D can vibrate. Specifically, the holding portion 140 is formed in plane symmetry with respect to the imaginary plane defined along the center line CL1. The holding portion 140 is shaped like a rectangular frame in plan view and is placed so as to surround an outer side portion of the vibrating portion 110 along the XY plane. Thus, the holding portion 140 surrounding the vibrating portion 110 can be easily implemented by provision of the shape of the frame in plan view for the holding portion 140.

Incidentally, it is sufficient if the holding portion 140 is placed in at least a portion of a periphery of the vibrating portion 110 and there is no limitation to the shape of the frame. For instance, it is sufficient if the holding portion 140 is placed in the periphery of the vibrating portion 110 to such an extent that the holding portion 140 can hold the vibrating portion 110 and can be jointed to the upper lid 30 and the lower lid 20.

In the embodiment, the holding portion 140 includes frame bodies 141A to 141D formed integrally. As illustrated in FIG. 3, the frame body 141A is provided so as to face the open ends of the vibrating arms 121A to 121D and so as to have a longitudinal direction parallel to the X axis. The frame body 141B is provided so as to face the rear end portion 131B of the base portion 130 and so as to have a longitudinal direction parallel to the X axis. The frame body 141C is provided so as to face the left end portion 131C of the base portion 130 and the vibrating arm 121A and so as to have a longitudinal direction parallel to the Y axis and both ends thereof are respectively connected to one end of the frame bodies 141A and 141B. The frame body 141D is provided so as to face the right end portion 131D of the base portion 130 and the vibrating arm 121D and so as to have a longitudinal direction parallel to the Y axis and both ends thereof are respectively connected to the other end of the frame bodies 141A and 141B. The frame bodies 141A and 141B face each other in the Y axis direction with the vibrating portion 110 interposed therebetween. The frame bodies 141C and 141D face each other in the X axis direction with the vibrating portion 110 interposed therebetween.

The support arm portion 150 is placed in the inner side portion of the holding portion 140 and makes a connection between the base portion 130 and the holding portion 140. The support arm portion 150 is formed so as not to be in line symmetry with respect to the center line CL1, that is, so as to be asymmetric. Specifically, the support arm portion 150 includes the one support arm 151 in plan view. The support arm 151 includes a support rear arm 152.

The support rear arm 152 extends from the holding portion 140 between the rear end portion 131B of the base portion 130 and the holding portion 140. Specifically, the support rear arm 152 has one end (left end or end on the side of the frame body 141C) connected to the frame body 141C and extends in the X axis direction toward the frame body 141D. That is, the one end of the support arm 151 is connected to the holding portion 140. Further, the support rear arm 152 is bent in the Y axis direction at a center of the base portion 130 with respect to the X axis direction, extends therefrom along the center line CL1, and is connected to the rear end portion 131B of the base portion 130. That is, the other end of the support arm 151 is connected to the rear end portion 131B of the base portion 130.

The protruding portion 25 protrudes from the recessed portion 21 of the lower lid 20 into the vibration space. The protruding portion 25 is placed between the arm portion 123B of the vibrating arm 121B and the arm portion 123C of the vibrating arm 121C in plan view. The protruding portion 25 extends in the Y axis direction in parallel with the arm portions 123B and 123C and is formed in a shape of a prism. The protruding portion 25 has a length on the order of 240 along the Y axis direction and a length on the order of 15 μm along the X axis direction. Incidentally, the number of the protruding portions 25 is not limited to one and may be two or more. Thus, by placement of the protruding portion 25 between the vibrating arm 121B and the vibrating arm 121C and protrusion thereof from the bottom plate 22 of the recessed portion 21, rigidity of the lower lid 20 can be increased and occurrence of flexure of the resonator 10 formed above the lower lid 20 or a warp of the lower lid 20 can be reduced.

An isolation groove 145 is configured so as to surround the vibrating portion 110 in plan view. More particularly, the isolation groove 145 is configured so as to surround the vibrating portion 110 and the support arm portion 150 that are placed inside the holding portion 140. Specifically, the isolation groove 145 is a groove that penetrates the resonator 10 from a front surface to a back surface thereof, is formed in a specified area of the holding portion 140, and has a substantially rectangular frame-like shape in plan view.

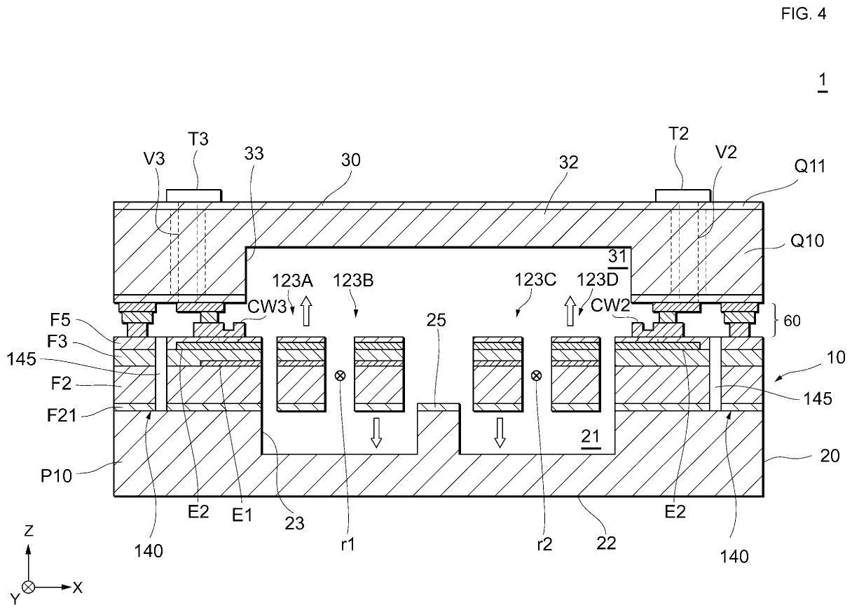

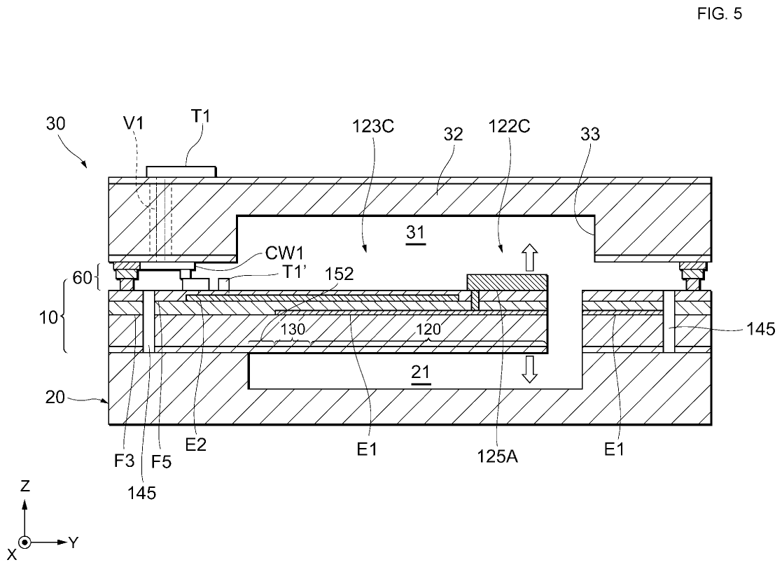

Subsequently, a stacking structure and operation of the resonance device according to the embodiment will be described with reference to FIGS. 4 and 5. FIG. 4 is a sectional view, taken along the X axis, schematically illustrating the stacking structure of the resonance device 1 illustrated in FIG. 1. FIG. 5 is a sectional view, taken along the Y axis, schematically illustrating the stacking structure of the resonance device 1 illustrated in FIG. 1.

In the resonance device 1, as illustrated in FIGS. 4 and 5, the holding portion 140 of the resonator 10 is jointed onto the side walls 23 of the lower lid 20 and then the holding portion 140 of the resonator 10 and the side walls 33 of the upper lid 30 are jointed. Thus, the resonator 10 is held between the lower lid 20 and the upper lid 30, so that the vibration space in which the vibrating portion 110 vibrates is formed by the lower lid 20, the upper lid 30, and the holding portion 140 of the resonator 10.

The vibrating portion 110, the holding portion 140, and the support arm portion 150 of the resonator 10 are integrally formed by an identical process. In the resonator 10, a metal film E1 is stacked on a Si substrate F2 that is an example of a substrate. Moreover, a piezoelectric film F3 is stacked on the metal film E1 so as to cover the metal film E1 and a metal film E2 is further stacked on the piezoelectric film F3. A protection film F5 is stacked on the metal film E2 so as to cover the metal film E2. In the mass addition portions 122A to 122D, furthermore, the aforementioned mass addition films 125A to 125D are each stacked on the protection film F5. Outer shapes of the vibrating portion 110, the holding portion 140, and the support arm portion 150 are formed by removal processing and patterning of a multilayer body composed of the aforementioned Si substrate F2, the metal film E1, the piezoelectric film F3, the metal film E2, the protection film F5, and the like through dry etching, for instance.

The Si substrate F2 is formed of degenerate n-type silicon (Si) semiconductor with a thickness on the order of 6 μm, for instance, and may include phosphorus (P), arsenic (As), antimony (Sb), or the like as n-type dopant. Also, a resistance value of the degenerate silicon (Si) used for the Si substrate F2 is smaller than 1.6 mΩ·cm, for instance, and is smaller than or equal to 1.2 mΩ·cm, more preferably. Further, a silicon oxide layer F21 made of SiO₂ or the like, for instance, is formed as an example of a temperature characteristics correction layer on a lower surface of the Si substrate F2. Thus, temperature characteristics can be improved.

In the embodiment, the silicon oxide layer F21 refers to a layer having a function of reducing a temperature coefficient, that is, a changing rate per temperature of frequency in the vibrating portion 110 with the temperature correction layer formed on the Si substrate F2, at least in a vicinity of ordinary temperature, compared with a case where the silicon oxide layer F21 is not formed on the Si substrate F2. With the vibrating portion 110 having the silicon oxide layer F21, a change with temperature in a resonant frequency of a multilayer structure body made of the Si substrate F2, the metal films E1 and E2, the piezoelectric film F3, and the silicon oxide layer F21 can be reduced, for instance. The silicon oxide layer may be formed on an upper surface of the Si substrate F2 or may be formed on both the upper surface of and the lower surface of the Si substrate F2.

It is desired that the silicon oxide layers F21 of the mass addition portions 122A to 122D should be formed with a uniform thickness. Incidentally, the uniform thickness means that a variation in the thicknesses of the silicon oxide layers F21 is within ±20% from an average value of the thicknesses.

The metal films E1 and E2 each includes an excitation electrode to excite the vibrating arms 121A to 121D and an extended electrode to make an electrical connection between the excitation electrode and an external power supply. Portions of the metal films E1 and E2 that fulfill a function of the excitation electrodes face each other with the piezoelectric film F3 interposed therebetween in the arm portions 123A to 123D of the vibrating arms 121A to 121D. Portions of the metal films E1 and E2 that fulfill a function of the extended electrodes extend through the support arm portion 150 and are derived from the base portion 130 to the holding portion 140, for instance. The metal film E1 is electrically continuous throughout the resonator 10. The metal film E2 is electrically isolated between portions formed in the vibrating arms 121A and 121D and portions formed in the vibrating arms 121B and 121C. The portions of the metal film E1 that fulfill the function of the excitation electrodes may be referred to as lower electrodes. The portions of the metal film E2 that fulfill the function of the excitation electrodes may be referred to as upper electrodes.

Thicknesses of the metal films E1 and E2 are approximately 0.1 μm to 0.2 μm, for instance. The metal films E1 and E2 are patterned into the excitation electrodes, the extended electrodes, and the like by removal processing such as etching after film formation. The metal films E1 and E2 are formed from metal material whose crystal structure is a body-centered cubic structure, for instance. Specifically, the metal films E1 and E2 are formed with use of molybdenum (Mo), tungsten (W), or the like. Thus, the metal films E1 and E2 that are suitable for lower electrodes and upper electrodes of the resonator 10 can be easily implemented with use of metal whose crystal structure is the body-centered cubic structure, as a main component.

Though the example in which the resonator 10 includes the metal film E1 has been disclosed in the embodiment, there is no limitation thereto. It is preferable that the Si substrate F2 included in the resonator 10 should be a substrate of degenerate silicon (which will be referred to as “degenerate silicon substrate” hereinbelow) resulting in low resistance, for instance, rather than simple silicon (Si). Thus, the metal film E1 can be omitted from the resonator 10 and it is made possible for the degenerate silicon substrate itself to hold a function of the metal film E1 such as a function of the lower electrode. Accordingly, in a collective substrate 100 that will be described later, sharing of the degenerate silicon substrate between adjoining resonance devices makes it possible for currents to be easily and collectively applied to the plurality of resonance devices via the degenerate silicon substrate, that is, the lower electrode of the plurality of resonators 10.

The piezoelectric film F3 is a thin film formed from a type of piezoelectric material that makes an interconversion between electric energy and mechanical energy. The piezoelectric film F3 expands and contracts in the Y axis direction among in-plane directions in the XY plane in accordance with an electric field formed in the piezoelectric film F3 by the metal films E1 and E2. With such expansion and contraction of the piezoelectric film F3, the vibrating arms 121A to 121D displace the open ends toward the bottom plate 22 of the lower lid 20 and a bottom plate 32 of the upper lid 30, respectively. Thus, the resonator 10 vibrates in the out-of-plane bending vibration mode.

Though a thickness of the piezoelectric film F3 is on the order of 1 μm, for instance, the thickness may be on the order of 0.2 μm to 2 μm. The piezoelectric film F3 is formed from material having a crystal structure of wurtzite-type hexagonal crystal structure and may include nitride or oxide such as aluminum nitride (AlN), scandium aluminum nitride (ScAlN), zinc oxide (ZnO), gallium nitride (GaN), or indium nitride (InN), for instance, as a main component. Incidentally, scandium aluminum nitride is made by substitution of scandium for a portion of aluminum in aluminum nitride and two elements such as magnesium (Mg) and niobium (Nb) or magnesium (Mg) and zirconium (Zr) may be substituted instead of scandium. Thus, the piezoelectric film F3 includes the piezoelectric material having the crystal structure of the wurtzite-type hexagonal crystal structure as the main component, so that the piezoelectric film F3 that is suitable for the resonator 10 can be easily implemented.

The protection film F5 protects the metal film E2 from oxidation. Incidentally, the protection film F5 does not have to be exposed to the bottom plate 32 of the upper lid 30 as long as the protection film F5 is provided on a side of the upper lid 30. For instance, a parasitic capacitance reduction film to reduce capacitance of interconnections formed in the resonator 10 or the like may be formed so as to cover the protection film F5. The protection film F5 is formed of a piezoelectric film such as aluminum nitride (AlN), scandium aluminum nitride (ScAlN), zinc oxide (ZnO), gallium nitride (GaN), or indium nitride (InN) or an insulating film such as silicon nitride (SiN), silicon oxide (SiO₂), alumina oxide (Al₂O₃), or tantalum pentoxide (Ta₂O₅), for instance. A thickness of the protection film F5, formed with a length that is smaller than or equal to half of the thickness of the piezoelectric film F3, is on the order of 0.2 μm, for instance, in the embodiment. Incidentally, a more preferable thickness of the protection film F5 is on the order of a quarter of the thickness of the piezoelectric film F3. Furthermore, in case where the protection film F5 is formed of piezoelectric material such as aluminum nitride (AlN), the piezoelectric material having the same orientation as the piezoelectric film F3 has is preferably used.

It is desired that the protection film F5 in the mass addition portions 122A to 122D should be formed with a uniform thickness. Incidentally, the uniform thickness means that a variation in the thicknesses of the protection film F5 is within ±20% from an average value of the thicknesses.

The mass addition films 125A to 125D configure surfaces of the mass addition portions 122A to 122D on a side of the upper lid 30 and correspond to the frequency regulation films of the vibrating arms 121A to 121D, respectively. A frequency of the resonator 10 is regulated with trimming processing in which a portion is removed from each of the mass addition films 125A to 125D. The mass addition films 125A to 125D are preferably formed from material having a mass reduction velocity with etching higher than the protection film F5 has, in terms of efficiency of frequency regulation. The mass reduction velocity is expressed by a product of etching velocity and density. The etching velocity is a thickness that is removed per unit time. Between the protection film F5 and the mass addition films 125A to 125D, magnitude relation of the etching velocity does not matter as long as relation of the mass reduction velocity is as described above. In addition, the mass addition films 125A to 125D are preferably formed from material having a large specific gravity in terms of efficient increase in weights of the mass addition portions 122A to 122D. For these reasons, the mass addition films 125A to 125D are formed from metal material such as molybdenum (Mo), tungsten (W), gold (Au), platinum (Pt), nickel (Ni), aluminum (Al), or titanium (Ti), for instance.

Portions of upper surfaces of the mass addition films 125A to 125D have been removed with trimming processing in a step of regulating the frequency. The trimming processing for the mass addition films 125A to 125D can be carried out through the dry etching with irradiation with an argon (Ar) ion beam, for instance. An ion beam is superior in processing efficiency because of capability of irradiation of a broad area, whereas there is a fear that the mass addition films 125A to 125D may be charged because the ion beam carries a charge. The mass addition films 125A to 125D are preferably grounded in order that the vibration characteristics of the resonator 10 may be prevented from being deteriorated with changes in vibratory tracks of the vibrating arms 121A to 121D that may be caused by a coulomb interaction with charging of the mass addition films 125A to 125D.

An inner terminal T1′ and connection wirings CW2 and CW3 are formed on the protection film F5 of the holding portion 140. The inner terminal T1′ is electrically connected to the metal film E1 via a through-hole formed on the piezoelectric film F3 and the protection film F5. Incidentally, on condition that the resonator 10 does not include the metal film E1, the inner terminal T1′ is electrically connected to the Si substrate F2 doubling as the metal film E1 via the through-hole.

The connection wiring CW2 is led as will be described later and is electrically connected to portions of the metal film E2 formed on the vibrating arms 121A and 121D. The connection wiring CW3 is led as will be described later and is electrically connected to portions of the metal film E2 formed on the vibrating arms 121B and 121C. The inner terminal T1′ and the connection wirings CW2 and CW3 are formed from metal material such as aluminum (Al), germanium (Ge), gold (Au), or tin (Sn).

The bottom plate 22 and the side walls 23 of the lower lid 20 are integrally formed as a Si substrate P10. The Si substrate P10 is formed of non-degenerate silicon having a resistivity greater than or equal to 10 Ω·cm, for instance. The Si substrate P10 is exposed in an inner side portion in the recessed portion 21 of the lower lid 20. The silicon oxide layer F21 is formed on an upper surface of the protruding portion 25. On the upper surface of the protruding portion 25, however, the Si substrate P10 having the lower electric resistivity than the silicon oxide layer F21 has may be exposed or a conductive layer may be formed in terms of reduction in charging in the protruding portion 25.

A thickness of the lower lid 20 defined in the Z axis direction is on the order of 150 μm and a depth of the recessed portion 21 defined similarly is on the order of 50 μm.

The bottom plate 32 and the side walls 33 of the upper lid 30 are integrally formed as a Si substrate Q10. A front surface and a back surface of the upper lid 30 and inside surfaces of the through-hole are preferably covered with an insulating oxide film Q11 such as a silicon oxide film. The insulating oxide film Q11 is formed on the front surfaces of the Si substrate Q10 by oxidation of the Si substrate Q10 or chemical vapor deposition (CVD), for instance. The Si substrate Q10 is exposed in an inner side portion in the recessed portion 31 of the upper lid 30. Incidentally, a getter layer may be formed on a surface of the recessed portion 31 of the upper lid 30 on a side facing the resonator 10. The getter layer is formed of titanium (Ti) or the like, for instance, and absorbs outgas released from the joint portion 60 that will be described later or the like so as to reduce loss of vacuum in the vibration space. Incidentally, the getter layer may be formed on a surface of the recessed portion 21 of the lower lid 20 on a side facing the resonator 10 or may be formed on the surfaces of both the recessed portion 21 of the lower lid 20 and the recessed portion 31 of the upper lid 30 on the side facing the resonator 10.

A thickness of the upper lid 30 defined in the Z axis direction is on the order of 150 μm and a depth of the recessed portion 31 defined similarly is on the order of 50 μm.

Outer terminals T1, T2, and T3 are formed on an upper surface (surface on a side opposed to the surface facing the resonator 10) of the upper lid 30. The outer terminal T1 is a mounting terminal to ground the metal film E1 of the resonator 10. The outer terminal T2 is a mounting terminal to electrically connect the metal film E2 of the vibrating arms 121A and 121D of the resonator 10 to the external power supply. The outer terminal T3 is a mounting terminal to electrically connect the metal film E2 of the vibrating arms 121B and 121C of the resonator 10 to the external power supply. The outer terminals T1, T2, and T3 are each formed of a metallization layer (foundation layer) of chromium (Cr), tungsten (W), nickel (Ni), or the like plated with nickel (Ni), gold (Au), silver (Ag), copper (Cu), or the like, for instance. Incidentally, a dummy terminal electrically insulated from the resonator 10 may be formed on the upper surface of the upper lid 30, for a purpose of regulating a parasitic capacitance or a mechanical strength balance.

Penetrating electrodes V1, V2, and V3 are formed in the side walls 33 of the upper lid 30. The penetrating electrode V1 makes an electrical connection between the outer terminal T1 and the inner terminal T1′ with a connection wiring CW1, to be described later, interposed therebetween. Meanwhile, the penetrating electrode V2 makes an electrical connection between the outer terminal T2 and the connection wiring CW2 and the penetrating electrode V3 makes an electrical connection between the outer terminal T3 and the connection wiring CW3. The penetrating electrodes V1, V2, and V3 are formed by filling with conductive material in the through-holes penetrating the side walls 33 of the upper lid 30 in the Z axis direction. The conductive material to be filled is polycrystalline silicon (Poly-Si), copper (Cu), gold (Au), or the like, for instance.

The connection wiring CW1 is formed on a surface of the side walls 33 of the upper lid 30 on the side facing the resonator 10. The connection wiring CW1 makes a connection between the penetrating electrode V1 and the inner terminal T1′. Thus, it is made possible for a current to be applied to the vibrating portion 110 (the excitation portion 120 and the base portion 130) of the resonator 10 via the connection wiring CW1 because the inner terminal T1′ is electrically connected to the metal film E1 of the resonator 10 as described above. Therefore, the vibration characteristics and the like of the resonator 10 can be measured from outside of the upper lid 30 via the outer terminal T1, the penetrating electrode V1, and the connection wiring CW1 in an inspection step, for instance. Incidentally, the connection wiring CW1 of the embodiment corresponds to an example of “first connection portion” of the invention.

The joint portion 60 is formed between the side walls 33 of the upper lid 30 and the holding portion 140 and the upper lid 30 is jointed to the MEMS substrate 50 (the lower lid 20 and the resonator 10) by the joint portion 60. The joint portion 60 is shaped like a closed loop surrounding the vibrating portion 110 in the XY plane, so as to airtightly seal the vibration space for the resonator 10 in the vacuum state.

The joint portion 60 has conductivity and is formed of a metal film in which aluminum (Al) film, germanium (Ge) film, and aluminum (Al) film are stacked in order of mention and are eutectically bonded, for instance. Incidentally, the joint portion 60 may be formed of a combination of films selected appropriately from gold (Au), tin (Sn), copper (Cu), titanium (Ti), silicon (Si), and the like. Further, the joint portion 60 may include a metal compound such as titanium nitride (TiN), tantalum nitride (TaN), or the like between the films, for improvement in close contact property.

Further, the connection wiring CW1 extends to an outer peripheral portion on the lower surface of the upper lid 30 and the joint portion 60 and the connection wiring CW1 are electrically connected.

The joint portion 60 is placed on an upper surface of the MEMS substrate 50 (the lower lid 20 and the resonator 10) at a specified distance on order of 20 μm, for instance, from outer edges thereof. Thus, product defects of the resonance device 1 can be reduced, such as protrusions (burrs) or shear drops resulting from a split defect which may occur on condition that the joint portion 60 is not spaced with the specified distance.

The isolation groove 145 is formed so as to penetrate the holding portion 140 from the protection film F5 formed on a front surface to the silicon oxide layer F21 on the lower surface of the Si substrate F2. Thus, outside of the resonator 10 is isolated from the vibrating portion 110 by the isolation groove 145 because the isolation groove 145 is formed so as to surround the vibrating portion 110 in plan view as described above and a conductive path leading from the outside of the resonator 10 via the holding portion 140 to the vibrating portion 110 is interrupted before the jointing. Therefore, noise propagation to the vibrating portion 110 via the holding portion 140 can be reduced and the resonant frequency can be regulated with high accuracy at time of the frequency regulation, for instance.

In the embodiment, the outer terminal T1 is grounded and alternating voltages opposed in phase to each other are applied to the outer terminal T2 and the outer terminal T3. Therefore, phases of an electric field formed in the piezoelectric film F3 of the vibrating arms 121A and 121D and phases of an electric field formed in the piezoelectric film F3 of the vibrating arms 121B and 121C are opposed to each other. Thus, the vibrating arms 121A and 121D in the outer side portions and the vibrating arms 121B and 121C in the inner side portion are displaced in directions opposed to each other.

When the mass addition portions 122A, 122D and the arm portions 123A, 123D of the vibrating arms 121A, 121D are displaced toward an inside surface of the upper lid 30 as illustrated in FIG. 4, for instance, the mass addition portions 122B, 122C and the arm portions 123B, 123C of the vibrating arms 121B, 121C are displaced toward an inside surface of the lower lid 20. When the mass addition portions 122A, 122D and the arm portions 123A, 123D of the vibrating arms 121A, 121D are inversely displaced toward the inside surface of the lower lid 20, though illustration is omitted, the mass addition portions 122B, 122C and the arm portions 123B, 123C of the vibrating arms 121B, 121C are displaced toward the inside surface of the upper lid 30. Accordingly, at least two of the four vibrating arms 121A to 121D bend out of plane with different phases.

In relation between the adjoining vibrating arms 121A and 121B, in this manner, the vibrating arm 121A and the vibrating arm 121B vibrate upward and downward in opposite directions around a center axis r1 extending in the Y axis direction. Meanwhile, in relation between the adjoining vibrating arms 121C and 121D, the vibrating arm 121C and the vibrating arm 121D vibrate upward and downward in opposite directions around a center axis r2 extending in the Y axis direction. Consequently, torsional moments in opposite directions are caused for the center axis r1 and the center axis r2, so that bending vibrations in the vibrating portion 110 are produced. Maximum amplitudes of the vibrating arms 121A to 121D are on the order of 50 μm and amplitudes thereof at time of normal driving are on the order of 10 μm.

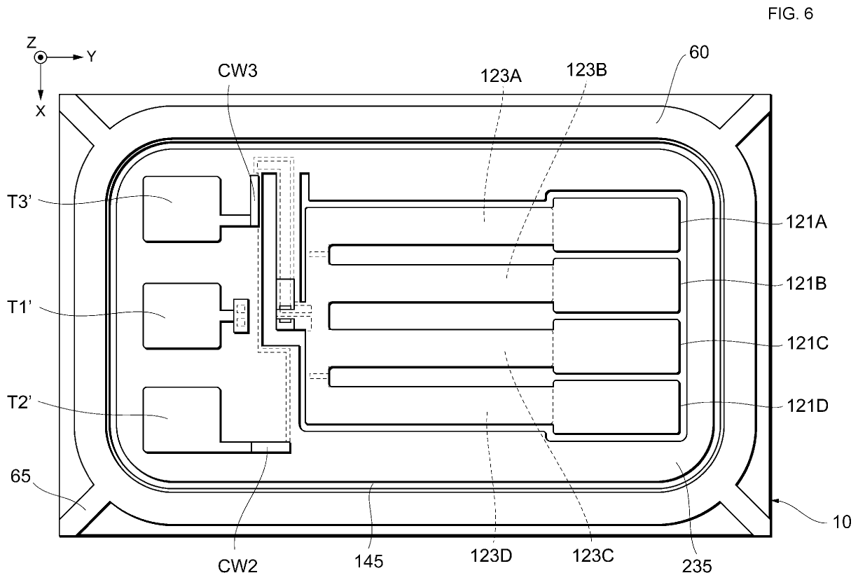

Subsequently, the resonator of the resonance device according to the embodiment and wiring therearound will be described with reference to FIG. 6. FIG. 6 is a plan view schematically illustrating the resonator 10 illustrated in FIGS. 1 to 5 and wiring therearound.

As illustrated in FIG. 6, inner terminals T1′, T2′, and T3′ are formed on the protection film F5 of the resonator 10 in an area inside the isolation groove 145. As described above, the inner terminal T1′ is electrically connected to the connection wiring CW1 formed on the upper lid 30 and is electrically connected via the through-hole to the metal film E1 embedded in the resonator 10.

The inner terminal T2′ is intended for making an electrical connection between the penetrating electrode V2 formed in the upper lid 30 and the connection wiring CW2 formed on the resonator 10. The connection wiring CW2 extends from the inner terminal T2′, is led, and is electrically connected to the metal film E2 formed on the arm portion 123B of the vibrating arm 121B and to the metal film E2 formed on the arm portion 123C of the vibrating arm 121C. The inner terminal T3′ is intended for making an electrical connection between the penetrating electrode V3 formed in the upper lid 30 and the connection wiring CW3 formed on the resonator 10. The connection wiring CW3 extends from the inner terminal T3′, is led, and is electrically connected to the metal film E2 formed on the arm portion 123A of the vibrating arm 121A and to the metal film E2 formed on the arm portion 123D of the vibrating arm 121D.

The inner terminals T2′ and T3′ and the connection wirings CW2 and CW3 are formed from metal material such as aluminum (Al), germanium (Ge), gold (Au), or tin (Sn), as with the inner terminal T1′ and the connection wiring CW1.

The joint portion 60 formed in a shape of the loop on the resonator 10 includes coupling members 65. In other words, the coupling members 65 are integrally formed with the joint portion 60 and are electrically connected to the joint portion 60. The coupling members 65 are respectively formed on four corner portions of the joint portion 60, for instance, and extend to outer edges of the resonator 10 in plan view. Thus, it is made possible for currents to be applied via the joint portions 60 and the coupling members 65 to the vibrating portions 110 of the plurality of resonance devices 1 in the collective substrate 100 that will be described later. Therefore, the vibration characteristics and the like of the plurality of resonators 10 can be collectively measured via the connection wiring CW1, the joint portions 60, and the coupling members 65 in the inspection step, for instance, so that productivity of the resonance device 1 can be improved.

Though the example in which the coupling members 65 are electrically connected to the corner portions of the joint portion 60 has been disclosed in the embodiment, there is no limitation thereto. The coupling members 65 may be connected to long sides or short sides of the joint portion 60 that is substantially rectangular in plan view, for instance, and may extend to the outer edges of the resonator 10. Further, the number of the coupling members 65 is not limited to four and it is sufficient if the number is at least one.

The isolation groove 145 that is formed so as to surround the vibrating portion 110 in plan view is placed in the area between the outer edges of the resonator 10 and the vibrating portion 110 in plan view. Thus, the noise propagation from the outer edges of the resonator 10 to the vibrating portion 110 can be easily reduced.

More particularly, the isolation groove 145 is placed along an inner periphery of the joint portion 60 in plan view. Thus, the isolation groove 145 that isolates the vibrating portion 110 from the outside of the resonator 10 and that interrupts the conductive path leading from the outside of the resonator 10 via the holding portion 140 to the vibrating portion 110 can be easily formed.

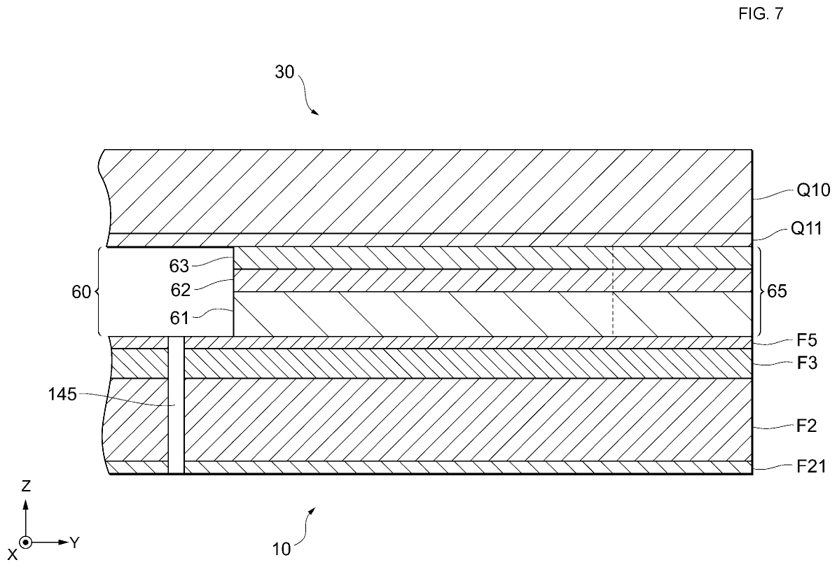

Subsequently, a stacking structure of the coupling members in the resonance device according to the embodiment will be described with reference to FIG. 7. FIG. 7 is an enlarged sectional view schematically illustrating the stacking structure of the coupling members 65 illustrated in FIG. 6.

As illustrated in FIG. 7, the joint portion 60 is configured so as to include a first metal layer 61, a second metal layer 62, and a third metal layer 63, for instance, from a side of the resonator 10 (MEMS substrate 50) toward a side of the upper lid 30.

The first metal layer 61 is a metal layer including aluminum (Al) as a main component, for instance, and material of the first metal layer 61 is aluminum (Al), aluminum-copper alloy (AlCu alloy), aluminum-silicon-copper alloy (AlSiCu alloy), or the like. The second metal layer 62 is a metal layer of germanium (Ge), for instance. Though the first metal layer 61 and the second metal layer 62 are represented as independent layers in an example illustrated in FIG. 7, an interface between the layers is eutectically bonded, actually. That is, the first metal layer 61 and the second metal layer 62 are configured by a eutectic alloy of metals including aluminum (Al) and germanium (Ge) as main components. The third metal layer 63 is a metal layer including aluminum (Al) as a main component, for instance, and material of the third metal layer 63 is aluminum (Al), aluminum-copper alloy (AlCu alloy), aluminum-silicon-copper alloy (AlSiCu alloy), or the like.

The coupling members 65 are integrally formed with the joint portion 60. That is, the coupling members 65 are configured so as to include the first metal layer 61, the second metal layer 62, and the third metal layer 63, as with the joint portion 60.

The coupling members 65 extend to the outer edges on the surface (upper surface in FIG. 7) of the MEMS substrate 50 (the lower lid 20 and the resonator 10) that faces the upper lid 30. Further, the coupling members 65 extend to outer edges on the surface (lower surface in FIG. 7) of the upper lid 30 that faces the MEMS substrate 50 (the lower lid 20 and the resonator 10). Thus, coupling of the adjoining coupling members 65 in the collective substrate 100 that will be described later enables sealing of spaces among the plurality of resonance devices 1. Therefore, incursion of chemicals or the like into gaps among the resonance devices 1 in the collective substrate 100 can be reduced.

### Collective Substrate

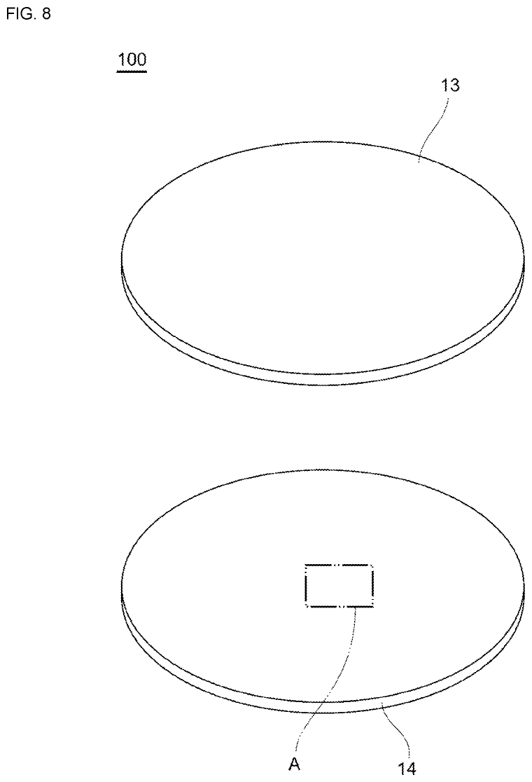

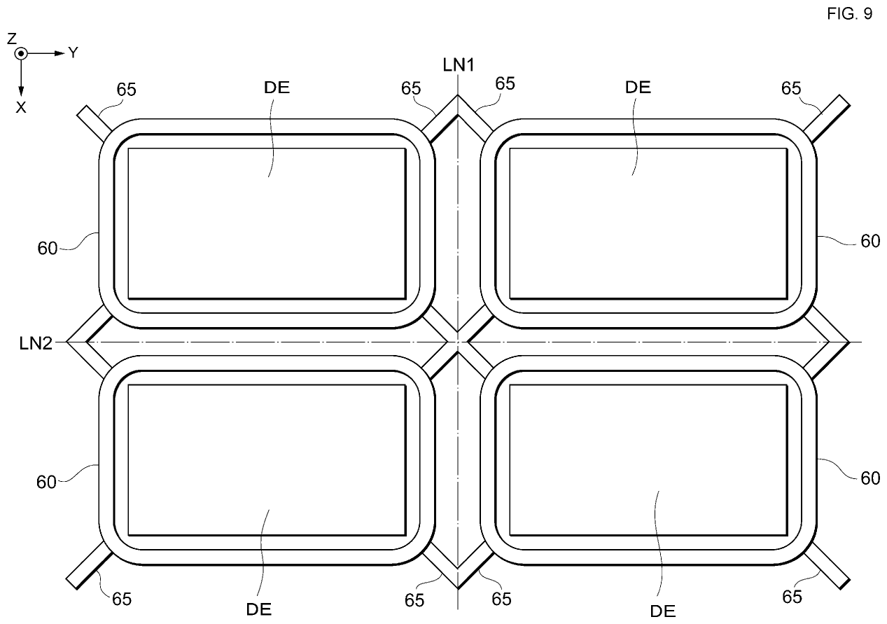

Subsequently, a schematic configuration of the collective substrate according to the embodiment will be described with reference to FIG. 8 and FIG. 9. FIG. 8 is an exploded perspective view schematically illustrating an exterior of the collective substrate 100 in the embodiment. FIG. 9 is an enlarged fragmentary view in which an area A illustrated in FIG. 8 is enlarged.

The collective substrate 100 of the embodiment is intended for manufacture of the resonance device 1 described above. As illustrated in FIG. 8, the collective substrate 100 includes an upper-side substrate 13 and a lower-side substrate 14. The upper-side substrate 13 and the lower-side substrate 14 each have a circular shape in plan view. The lower-side substrate 14 includes the plurality of resonators 10. The Si substrates F2 included in the plurality of resonators 10 may be degenerate silicon substrates as described above. The upper-side substrate 13 is placed so as to have a lower surface facing the lower-side substrate 14 with the plurality of resonators 10 interposed therebetween. Incidentally, the lower-side substrate 14 of the embodiment corresponds to an example of “first substrate” of the invention and the upper-side substrate 13 of the embodiment corresponds to an example of “second substrate” of the invention.

As illustrated in FIG. 9, a plurality of devices DE and the plurality of joint portions 60 are formed on an upper surface of the lower-side substrate 14. Each of the devices DE corresponds to major portions of the resonator 10 described above, such as the vibrating portion 110 and the support arm portion 150 that are placed inside the isolation groove 145. The joint portions 60 are each provided in an area of the holding portion 140 of the resonator 10. Further, each of the joint portions 60 includes the coupling members 65 on the rectangular corner portions, respectively. Sets of the devices DE and the joint portions 60 are placed like an array on the entire upper surface of the lower-side substrate 14. Specifically, the plurality of sets are placed at specified intervals in a row direction (direction along the Y axis in FIG. 9) and in a column direction (direction along the X axis in FIG. 9).

Split lines LN1 and LN2 illustrated in FIG. 9 are intended for split of the collective substrate 100, that is, the upper-side substrate 13 and the lower-side substrate 14 into the plurality of resonance devices 1 with cutting or the like and may be referred to as scribe lines. Widths of the split lines LN1 and LN2 are 5 μm to 20 μm, for instance.

The coupling members 65 each extend beyond the split lines LN1 and LN2. That is, the coupling members 65 of one of the joint portions 60 are coupled to the coupling members 65 of the joint portions 60 that have corner portions facing corner portions of the one joint portion 60, among the plurality of adjoining joint portions 60. As a result, the plurality of joint portions 60 are electrically connected to one another by the coupling members 65.

### MEMS Device Manufacturing Method

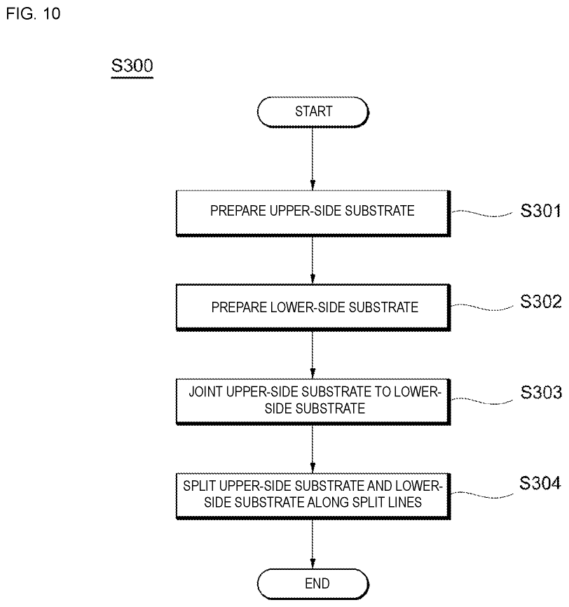

Subsequently, a resonance device manufacturing method according to the embodiment will be described. FIG. 10 is a flowchart representing the manufacturing method of the resonance device 1 in the embodiment.

As illustrated in FIG. 10, the upper-side substrate 13 corresponding to the upper lid 30 of the resonance device 1 is initially prepared (S301).

The upper-side substrate 13 is formed with use of a Si substrate. Specifically, the upper-side substrate 13 is formed of the Si substrate Q10 illustrated in FIG. 4 and having a specified thickness. The front surface and the back surface (surface facing the resonator 10) of the Si substrate Q10 and side surfaces of the penetrating electrodes V1, V2, and V3 are covered with the insulating oxide film Q11. The insulating oxide film Q11 is formed on the front surfaces of the Si substrate Q10 by oxidation of the front surfaces of the Si substrate Q10 or chemical vapor deposition (CVD), for instance.

The plurality of outer terminals T1, T2, and T3 are formed on the upper surface of the upper-side substrate 13. The outer terminals T1, T2, and T3 are each formed of a metallization layer (foundation layer) of chromium (Cr), tungsten (W), nickel (Ni), or the like plated with nickel (Ni), gold (Au), silver (Ag), copper (Cu), or the like, for instance.

Further, the penetrating electrodes V2 and V3 illustrated in FIG. 4 and the penetrating electrode V1 illustrated in FIG. 5 are formed by filling with conductive material in through-holes formed on the upper-side substrate 13. The conductive material to be filled is impurity-doped polycrystalline silicon (Poly-Si), copper (Cu), gold (Au), impurity-doped single-crystal silicon, or the like, for instance.

Meanwhile, the connection wiring CW1 to be electrically connected to the joint portion 60 is formed on the lower surface of the upper-side substrate 13. The connection wiring CW1 is formed on the lower surface of the upper-side substrate 13 by patterning with use of metal material such as aluminum (Al), germanium (Ge), gold (Au), or tin (Sn).

Subsequently, the lower-side substrate 14 corresponding to the MEMS substrate 50 (the resonator 10 and the lower lid 20) of the resonance device 1 is prepared (S302).

In the lower-side substrate 14, the Si substrates are jointed to one another. Incidentally, the lower-side substrate 14 may be formed with use of an SOI substrate. As illustrated in FIG. 4, the lower-side substrate 14 includes the Si substrate P10 and the Si substrate F2.

The metal film E1, the piezoelectric film F3, the metal film E2, and the protection film F5 are stacked on the upper surface of the Si substrate F2. The mass addition film 125A to 125D is stacked on the protection film F5 and the joint portions 60 are formed along the split lines LN1 and LN2 illustrated in FIG. 9 and at the specified distance therefrom. The joint portions 60 are formed so as to include the coupling members 65 that couple the adjoining joint portions 60. Outer shapes of the vibrating portion 110, the holding portion 140, the support arm portion 150, and the isolation groove 145 of the resonator 10 are formed by removal processing and patterning of the multilayer body through dry etching, for instance.

Further, on the protection film F5, the inner terminals T1′, T2′, and T3′ and the connection wirings CW2 and CW3 that are illustrated in FIG. 6 are formed in addition to the joint portion 60. Manufacturing processes can be simplified by use of metal of the same type as the joint portion 60, as material of the inner terminals T1′, T2′, and T3′ and the connection wirings CW2 and CW3.

Though an example in which the joint portion 60, the inner terminals T1′, T2′, and T3′, and the connection wirings CW2 and CW3 are formed on a side of the upper surface of the lower-side substrate 14 has been disclosed in the embodiment, there is no limitation thereto. For instance, at least one of the joint portion 60, the inner terminals T1′, T2′, and T3′, and the connection wirings CW2 and CW3 may be formed on a side of the lower surface of the upper-side substrate 13. Further, on condition that the joint portion 60 is configured by a plurality of materials, a portion of the materials, such as germanium (Ge), of the joint portion 60 may be formed on the side of the lower surface of the upper-side substrate 13 and remainder of the materials, such as aluminum (Al), of the joint portion 60 may be formed on the side of the upper surface of the lower-side substrate 14. Similarly, on condition that the inner terminals T1′, T2′, and T3′ and the connection wirings CW2 and CW3 are configured by a plurality of materials, a portion of the materials of the inner terminals T1′, T2′, and T3′ and the connection wirings CW2 and CW3 may be formed on the side of the lower surface of the upper-side substrate 13 and remainder of the materials of the inner terminals T1′, T2′, and T3′ and the connection wirings CW2 and CW3 may be formed on the side of the upper surface of the lower-side substrate 14.

Further, though the example in which the upper-side substrate 13 is prepared in step S301 and in which the lower-side substrate 14 is thereafter prepared in step S302 has been disclosed in the embodiment, there is no limitation thereto. For instance, order may be reversed so that the upper-side substrate 13 may be prepared after preparation of the lower-side substrate 14 or preparation of the upper-side substrate 13 and the preparation of the lower-side substrate 14 may be made in parallel.

Subsequently, the upper-side substrate 13 prepared in step S301 is jointed to the lower-side substrate 14 prepared in step S302 (S303).

Specifically, the lower surface of the upper-side substrate 13 and the upper surface of the lower-side substrate 14 are eutectically bonded by agency of the joint portions 60. As illustrated in FIG. 5, for instance, the upper-side substrate 13 and the lower-side substrate 14 are positioned so that the connection wiring CW1 formed on the upper-side substrate 13 is brought into contact with the inner terminal T1′ formed on the lower-side substrate 14. After positioning, the upper-side substrate 13 and the lower-side substrate 14 are interposed between heaters or the like and a heating process for eutectic bonding is carried out. Temperatures in the heating process for the eutectic bonding are higher than or equal to a eutectic temperature, such as 424° C. or higher and a heating duration is approximately 10 minutes or longer and 20 minutes or shorter, for instance. During the heating, the upper-side substrate 13 and the lower-side substrate 14 are pressed under a pressure of approximately 5 MPa or higher and 25 MPa or lower, for instance. Thus, the joint portions 60 eutectically bond the lower surface of the upper-side substrate 13 and the upper surface of the lower-side substrate 14.

Subsequently, the upper-side substrate 13 and the lower-side substrate 14 are split along the split lines LN1 and LN2 (S304).

For the split of the upper-side substrate 13 and the lower-side substrate 14, dicing may be carried out by cutting of the upper-side substrate 13 and the lower-side substrate 14 with use of a dicing saw or dicing may be carried out with use of a stealth dicing technique in which modified layers are formed in the substrates by focusing of laser.

By the split of the upper-side substrate 13 and the lower-side substrate 14 along the split lines LN1 and LN2 in step 5304, the upper-side substrate 13 and the lower-side substrate 14 are individuated (chipped) into each of the resonance devices 1 including the upper lid 30 and the MEMS substrate 50 (the lower lid 20 and the resonator 10).

In addition, the coupling members 65 extending beyond the split lines LN1 and LN2 are severed with the split of the upper-side substrate 13 and the lower-side substrate 14, as described above. Consequently, the coupling members 65 are each made to extend to the outer edges of the resonator 10 of each of the resonance devices 1.

Subsequently, a modification of the embodiment described above will be described. Incidentally, configurations that are the same as or similar to those illustrated in FIGS. 1 to 10 are provided with the same or similar reference characters and description thereof is omitted appropriately. Meanwhile, similar function effects resulting from similar configurations will not be referred to one by one.

### Modification

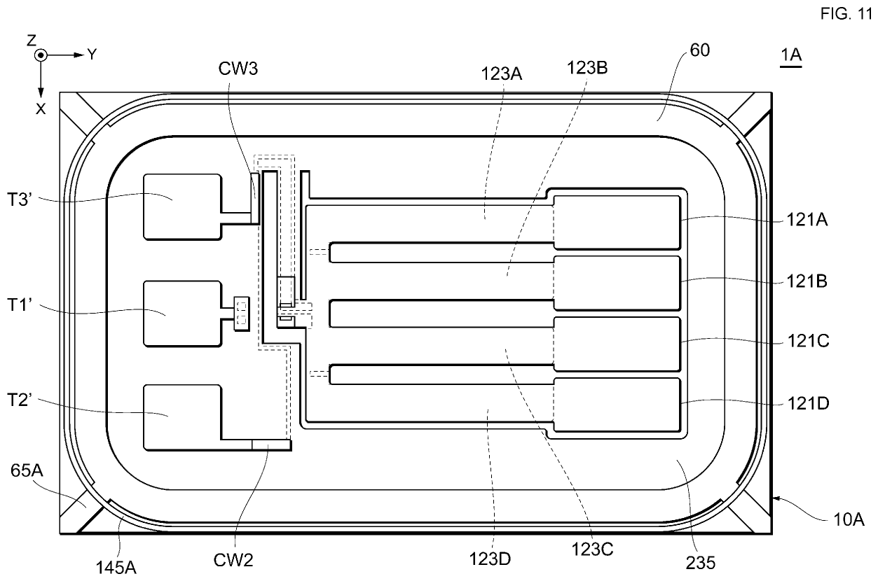

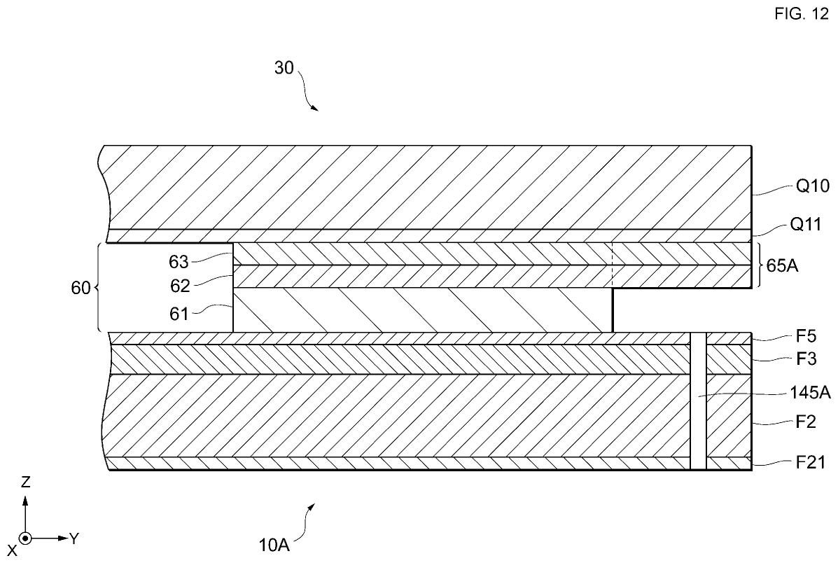

FIG. 11 is a plan view schematically illustrating a resonator 10A of a resonance device 1A in a modification of the embodiment and wiring therearound. FIG. 12 is an enlarged sectional view schematically illustrating a stacking structure of coupling members 65A illustrated in FIG. 11.

As illustrated in FIG. 11, the resonator 10A of the resonance device 1A includes an isolation groove 145A. As with the isolation groove 145 illustrated in FIG. 6, the isolation groove 145A has a substantially rectangular frame-like shape in plan view and is formed so as to surround the vibrating portion 110 of the resonator 10A. Meanwhile, the isolation groove 145A is formed in an area of the holding portion 140 that differs from the isolation groove 145 illustrated in FIG. 6. That is, the isolation groove 145A is placed along an outer periphery of the joint portion 60 in plan view. Thus, the isolation groove 145A that isolates the vibrating portion 110 from outside of the resonator 10A and that interrupts a conductive path leading from the outside of the resonator 10A via the holding portion 140 to the vibrating portion 110 can be easily formed.

The joint portion 60 of the resonance device 1A is formed in a shape of a loop on the resonator 10A and includes coupling members 65A. As with the coupling members 65 illustrated in FIG. 6, the coupling members 65A are respectively formed on the four corner portions of the joint portion 60.

Meanwhile, as illustrated in FIG. 12, the coupling members 65A are integrally formed with the second metal layer 62 and the third metal layer 63 of the joint portion 60. That is, the coupling members 65A do not include the first metal layer 61, unlike the coupling member 65 illustrated in FIG. 7.

In the resonator 10A, the isolation groove 145A is formed in the area between the joint portion 60 and the outer edges. Accordingly, the coupling members 65A extend to the outer edges on the surface (lower surface in FIG. 12) of the upper lid 30 that faces the MEMS substrate 50 (the lower lid 20 and the resonator 10).

The exemplary embodiment of the invention has been described above. The resonance device according to the embodiment includes the upper lid that is placed so as to face the MEMS substrate (the lower lid and the resonator) with the resonator interposed therebetween and that includes the connection wiring to be electrically connected to the vibrating portion. Thus, it is made possible for a current to be applied to the vibrating portion (the excitation portion and the base portion) of the resonator via the connection wiring. Therefore, the vibration characteristics and the like of the resonator can be measured from the outside of the upper lid via the outer terminal, the penetrating electrode, and the connection wiring in the inspection step, for instance. In addition, the resonator further includes the isolation groove that is formed so as to surround the vibrating portion in plan view. Thus, the vibrating portion is isolated from the outside of the resonator by the isolation groove and the conductive path leading from the outside of the resonator via the holding portion to the vibrating portion is interrupted before the jointing. Therefore, the noise propagation to the vibrating portion via the holding portion can be reduced and the resonant frequency can be regulated with high accuracy at the time of the frequency regulation, for instance.

In addition, the resonance device described above further includes the joint portion to joint the upper lid to the MEMS substrate (the lower lid and the resonator) so as to seal the vibration space for the resonator, the joint portion having conductivity and to be electrically connected to the connection wiring, and the coupling members electrically connected to the joint portion and extending to the outer edges of the resonator in plan view. Thus, it is made possible for currents to be applied via the joint portions and the coupling members to the vibrating portions of the plurality of resonance devices in the collective substrate. Therefore, the vibration characteristics and the like of the plurality of resonators can be collectively measured via the connection wirings, the joint portions, and the coupling members in the inspection step, for instance, so that the productivity of the resonance device can be improved.

Further, in the resonance device described above, the coupling members extend to the outer edges on the surface of the MEMS substrate (the lower lid and the resonator) that faces the upper lid and on the surface of the upper lid that faces the MEMS substrate (the lower lid and the resonator). Thus, the coupling of the adjoining coupling members in the collective substrate enables the sealing of the spaces among the plurality of resonance devices. Therefore, the incursion of chemicals or the like into the gaps among the resonance devices in the collective substrate can be reduced.

Further, in the resonance device described above, the isolation groove is placed along the outer periphery of the joint portion in plan view. Thus, the isolation groove that isolates the vibrating portion from the outside of the resonator and that interrupts the conductive path leading from the outside of the resonator via the holding portion to the vibrating portion can be easily formed.

Further, in the resonance device described above, the isolation groove is placed along the inner periphery of the joint portion in plan view. Thus, the isolation groove that isolates the vibrating portion from the outside of the resonator and that interrupts the conductive path leading from the outside of the resonator via the holding portion to the vibrating portion can be easily formed.

Further, in the resonance device described above, the isolation groove is placed between the outer edges of the resonator and the vibrating portion in plan view. Thus, the noise propagation from the outer edges of the resonator to the vibrating portion can be easily reduced.

In addition, in the resonance device described above, the resonator 10 further includes the degenerate silicon substrate. Thus, the metal film can be omitted from the resonator and it is made possible for the degenerate silicon substrate itself to hold the function of the metal film such as the function of the lower electrode. Accordingly, in the collective substrate, the sharing of the degenerate silicon substrate between adjoining resonance devices makes it possible for currents to be easily and collectively applied to the plurality of resonance devices via the degenerate silicon substrate, that is, the lower electrode of the plurality of resonators.

Further, the collective substrate according to the embodiment includes the upper-side substrate that is placed so as to face the lower-side substrate with the plurality of resonators interposed therebetween and that includes the plurality of connection wirings to be respectively and electrically connected to the vibrating portions of the plurality of resonators. Thus, it is made possible for a current to be applied to the vibrating portion (the excitation portion and the base portion) of the resonator via the connection wiring. Therefore, the vibration characteristics and the like of the resonators can be measured from the outside of the upper-side substrate via the outer terminals, the penetrating electrodes, and the connection wirings in the inspection step, for instance. In addition, each of the plurality of resonators further includes the isolation groove that is formed so as to surround the vibrating portion in plan view. Thus, the vibrating portion is isolated from the outside of the resonator by the isolation groove and the conductive path leading from the outside of the resonator via the holding portion to the vibrating portion is interrupted before the jointing. Therefore, the noise propagation to the vibrating portion via the holding portion can be reduced and the resonant frequency can be regulated with high accuracy at the time of the frequency regulation, for instance.

In addition, the collective substrate described above further includes the plurality of joint portions to joint the lower-side substrate to the upper-side substrate so as to respectively seal the vibration spaces for the resonators, the plurality of joint portions having conductivity and to be respectively and electrically connected to the plurality of connection wirings, and the coupling members electrically connected to the plurality of joint portions and extending beyond the split lines, intended for the split into the plurality of resonance devices, in plan view. Thus, it is made possible for currents to be applied via the joint portions and the coupling members to the vibrating portions of the plurality of resonance devices in the collective substrate. Therefore, the vibration characteristics and the like of the plurality of resonators can be collectively measured via the connection wirings, the joint portions, and the coupling members in the inspection step, for instance, so that the productivity of the resonance device can be improved.

Further, in the collective substrate described above, the coupling members extend beyond the split lines on the surface of the lower-side substrate that faces the upper-side substrate and on the surface of the anterosuperior-side substrate that faces the lower-side substrate. Thus, the adjoining coupling members are coupled in the collective substrate 100, so that the spaces among the plurality of resonance devices can be sealed. Therefore, the incursion of chemicals or the like into the gaps among the resonance devices in the collective substrate can be reduced.

In addition, in the collective substrate described above, the plurality of resonators further include the degenerate silicon substrates. Thus, the metal film can be omitted from the resonator and it is made possible for the degenerate silicon substrate itself to hold the function of the metal film such as the function of the lower electrode. Accordingly, in the collective substrate, the sharing of the degenerate silicon substrate between adjoining resonance devices makes it possible for currents to be easily and collectively applied to the plurality of resonance devices via the degenerate silicon substrate, that is, the lower electrode of the plurality of resonators.

Further, a resonance device manufacturing method according to the embodiment includes a step of preparing the lower-side substrate including the plurality of resonators each including the vibrating portion and the holding portion configured to hold the vibrating portion and the upper-side substrate that is placed so as to face the lower-side substrate with the plurality of resonators interposed therebetween and that includes the plurality of connection wirings to be respectively and electrically connected to the vibrating portions of the plurality of resonators. Thus, it is made possible for currents to be applied to the vibrating portions (the excitation portions and the base portions) of the resonators via the connection wirings. Therefore, the vibration characteristics and the like of the resonators can be measured from the outside of the upper-side substrate via the outer terminals, the penetrating electrodes, and the connection wirings in the inspection step, for instance. In addition, each of the plurality of resonators further includes the isolation groove that is formed so as to surround the vibrating portion in plan view. Thus, the vibrating portion is isolated from the outside of the resonator by the isolation groove and the conductive path leading from the outside of the resonator via the holding portion to the vibrating portion is interrupted before the jointing. Therefore, the noise propagation to the vibrating portion via the holding portion can be reduced and the resonant frequency can be regulated with high accuracy at the time of the frequency regulation, for instance.

Incidentally, the embodiment described above is intended for facilitating understanding of the present invention and are not intended for limitedly interpreting the invention. Modifications/improvements of the invention may be made without departing from the purport thereof and equivalents of the invention are also included in the invention. That is, the embodiment and/or modification changed appropriately in design by those skilled in the art are encompassed by the scope of the invention, as long as features of the invention are provided therein. For instance, elements provided in the embodiment and/or modification and placement, material, condition, shape, size, and the like thereof are not limited to those exemplified and can be appropriately changed. Additionally, the embodiment and/or modification are exemplary, it goes without saying that partial substitution or combination of configurations disclosed in different embodiment and/or modification can be made, and these are also encompassed by the scope of the invention as long as features of the invention are included therein.

### REFERENCE SIGNS LIST

1, 1A resonance device
10, 10A resonator
13 upper-side substrate
14 lower-side substrate
20 lower lid
21 recessed portion
22 bottom plate
23 side wall
25 protruding portion
30 upper lid
31 recessed portion
32 bottom plate
33 side wall
50 MEMS substrate
60 joint portion
61 first metal layer
62 second metal layer
63 third metal layer
65, 65A coupling member
100 collective substrate
110 vibrating portion
120 excitation portion
121, 121A, 121B, 121C, 121D vibrating arm
122A, 122B, 122C, 122D mass addition portion
123A, 123B, 123C, 123D arm portion
125A, 125B, 125C, 125D mass addition film
130 base portion
131A fore end portion
131B rear end portion
131C left end portion
131D right end portion
140 holding portion
141A, 141B, 141C, 141D frame body
145, 145A isolation groove
150 support arm portion
151 support arm
152 support rear arm
CL1 center line
CW1, CW2, CW3 connection wiring
DE device
E1, E2 metal film
F2 Si substrate
F3 piezoelectric film
F5 protection film
F21 silicon oxide layer
LN1, LN2 split line
P10 Si substrate
Q10 Si substrate

Q11 insulating oxide film
r1, r2 center axis
S301, S302, S303, S304 step
T1, T2, T3 outer terminal
T1′, T2′, T3′ inner terminal
V1, V2, V3 penetrating electrode
W1, W2 release width

1. A resonance device comprising:
a first substrate including a resonator having a vibrating portion, a holding portion configured to hold the vibrating portion, and an isolation groove that surrounds the vibrating portion in a plan view of the resonance device; and
a second substrate facing the first substrate with the resonator interposed therebetween and that includes a first connection portion electrically connected to the vibrating portion.

2. The resonance device according to claim 1, further comprising:
a joint portion jointing the first substrate to the second substrate and sealing a vibration space for the resonator, the joint portion having conductivity and electrically connected to the first connection portion; and
a second connection portion electrically connected to the joint portion and extending to outer edges of the resonator in the plan view.

3. The resonance device according to claim 2, wherein the second connection portion extends to the outer edges on a surface of the first substrate that faces the second substrate and on a surface of the second substrate that faces the first substrate.

4. The resonance device according to claim 2, wherein the isolation groove extends along an outer periphery of the joint portion in the plan view.

5. The resonance device according to claim 2, wherein the isolation groove extends along an inner periphery of the joint portion in the plan view.

6. The resonance device according to claim 1, wherein the isolation groove is between outer edges of the resonator and the vibrating portion in the plan view.

7. The resonance device according to claim 2, wherein the isolation groove is configured such that a conductive path from an outside of the resonator via the holding portion to the vibrating portion is interrupted by the isolation groove before the jointing by the joint portion.

8. The resonance device according to claim 1, wherein the resonator further includes a degenerate silicon substrate.

9. A collective substrate for manufacture of a resonance device, the collective substrate comprising:
a first substrate having a plurality of resonators each having a vibrating portion, a holding portion configured to hold the vibrating portion, and an isolation groove that surrounds the vibrating portion in a plan view of the collective substrate; and
a second substrate facing the first substrate with the plurality of resonators interposed therebetween and that includes a plurality of first connection portions respectively electrically connected to the vibrating portions of the plurality of resonators.

10. The collective substrate according to claim 9, further comprising:
a plurality of joint portions jointing the first substrate to the second substrate and sealing respective vibration spaces for the resonators, the plurality of joint portions having conductivity and respectively electrically connected to the plurality of first connection portions; and
a second connection portion electrically connected to the plurality of joint portions and extending beyond split lines for splitting the collective substrate into a plurality of resonance devices, in the plan view.

11. The collective substrate according to claim 10, wherein the second connection portion extends beyond the split lines on a surface of the first substrate that faces the second substrate and on a surface of the second substrate that faces the first substrate.

12. The collective substrate according to claim 10, wherein the isolation groove of each of the plurality of resonators extends along an outer periphery of a respective joint portion of the plurality of joint portions in the plan view.

13. The collective substrate according to claim 10, wherein the isolation groove of each of the plurality of resonators extends along an inner periphery of a respective joint portion of the plurality of joint portions in the plan view.

14. The collective substrate according to claim 10, wherein the isolation groove is configured such that a conductive path from an outside of each of the plurality of resonators via the holding portion to the vibrating portion is interrupted by the isolation groove before the jointing by the plurality of joint portions.

15. The collective substrate according to claim 9, wherein the plurality of resonators each further include a degenerate silicon substrate.

16. A method of manufacturing resonance devices, the method comprising:
preparing a first substrate including a plurality of resonators each having a vibrating portion, a holding portion configured to hold the vibrating portion, and an isolation groove that surrounds the vibrating portion in a plan view of the first substrate;
placing a second substrate so as to face the first substrate with the plurality of resonators interposed therebetween and that includes a plurality of first connection portions to be respectively and electrically connected to the vibrating portions of the plurality of resonators;
jointing the first substrate to the second substrate; and
splitting the first substrate and the second substrate along split lines so as to form a plurality of resonance devices.
